(19) United States
(12) Patent Application Publication
(10) Pub. No.: US 2026/0247525 A1
(43) Pub. Date: Aug. 20, 2026

(54) CIRCUIT BOARD ASSEMBLY AND RECHARGEABLE BATTERY INCLUDING THE CIRCUIT BOARD ASSEMBLY

(71) Applicant: SAMSUNG SDI CO., LTD., Yongin-si (KR)

(72) Inventors: Kangmin LEE, Yongin-si (KR); Byeongjo KIM, Yongin-si (KR)

(21) Appl. No.: 19/280,389

(22) Filed: Jul. 25, 2025

(30) Foreign Application Priority Data
Feb. 20, 2025 (KR) 10-2025-0022573

(51) Int. Cl. H05K 1/02; H01M 50/105; H01M 50/574; H05K 1/11; H05K 1/14; H05K 1/18; H05K 7/14

(52) U.S. Cl. CPC H05K 1/028; H01M 50/105; H01M 50/574; H05K 1/111; H05K 1/14; H05K 1/181; H05K 7/1427

(57) ABSTRACT

A circuit board assembly includes an integrated module including a first internal connection terminal and a second internal connection terminal each of which is connected to an electrode assembly of a rechargeable battery, the integrated module also including a rechargeable battery protection circuit component. A first flexible printed circuit board is connected to a first side of the integrated module and including a first external connection terminal connected to outside of the integrated module. A second flexible printed circuit board is connected to a second side of the above integrated module and including a second external connection terminal connected to outside of the circuit board assembly. In a horizontal direction for the integrated module, (i) the first internal connection terminal and the second internal connection terminal may be disposed adjacent to each other, and (ii) the second internal connection terminal may be positioned between the first internal connection terminal and the rechargeable battery protection circuit component.

### CROSS-REFERENCE TO RELATED APPLICATION

This application claims priority to and the benefit of Korean Patent Application No. 10-2025-0022573 filed with the Korean Intellectual Property Office on Feb. 20, 2025, the entire contents of which are incorporated herein by reference.

### BACKGROUND

### (a) Technical Field

The present disclosure relates to a circuit board assembly and a rechargeable battery including the circuit board assembly.

### (b) Description of the Related Art

Unlike a primary battery that cannot be recharged, secondary/rechargeable battery can be recharged and discharged. A low-capacity rechargeable battery is used, for example, as the power supply for small electronic devices, such as cellular phones, notebook computers and camcorders. A high-capacity rechargeable battery is used, for example, as the power supply for driving motors in hybrid vehicles and the like.

A rechargeable battery may include a flexible printed circuit board (FPCB) that is electrically connected to each battery cell to detect an information about the battery cell (e.g., a voltage and current information) and transmit that information.

The flexible printed circuit board may be connected to an integrated module having connection terminals connected to each battery cell and various protection circuit components positioned thereon.

As demand for high-capacity rechargeable battery has increased, the capacity of the battery cells accommodated in the battery packs has also increased. To meet these specifications, a flexible printed circuit board connected to both sides of the integrated module may be used. This structure may result in unfavorable current flow because, depending on the arrangement of the connection terminals and protection circuit components arranged in the integrated module, the current flow may bypass the interior of the integrated module.

The information disclosed in this section is only intended to enhance the understanding of the background of the present disclosure and may include information that does not constitute prior art.

### SUMMARY

The present disclosure provides a circuit board assembly for improving the efficiency of the current flow in an integrated module connected to a rechargeable battery and a rechargeable battery including the circuit board assembly.

The technical objects to be solved by the present disclosure are not limited to the problems described above and other objects not mentioned may be clearly understood by those skilled in the art from the description below.

A circuit board assembly according to the present disclosure includes an integrated module including a first internal connection terminal and a second internal connection terminal each of which is connected to an electrode assembly of a rechargeable battery, the integrated module also including a rechargeable battery protection circuit component; a first flexible printed circuit board connected to a first side of the integrated module and including a first external connection terminal connected to outside of the circuit board assembly; and a second flexible printed circuit board connected to a second side of the integrated module and including a second external connection terminal connected to outside of the circuit board assembly. In a horizontal direction for the integrated module, (i) the first internal connection terminal and the second internal connection terminal may be disposed adjacent to each other, and (ii) the second internal connection terminal may be positioned between the first internal connection terminal and the rechargeable battery protection circuit component.

The integrated module may include a first substrate layer and a second substrate layer facing to each other, and a conductive pattern layer disposed between the first substrate layer and the second substrate layer.

The first substrate layer may include a first printed circuit board including first and second surfaces facing each other, the second substrate layer may include a second printed circuit board including third and fourth surfaces facing each other, the conductive pattern layer may be disposed between the second surface and the fourth surface, and the first internal connection terminal and the second internal connection terminal may be disposed on the third surface.

The rechargeable battery protective circuit component may include a first protection IC chip, a first shunt resistor, and a first field effect transistor disposed on the first surface; and a second shunt resistor, a second protection IC chip, and a second field effect transistor disposed on the third surface.

The first flexible printed circuit substrate may further include a first connection pad connected to the first side of the integrated module; and a first connecting portion connecting the first connecting pad and the first external connecting terminal.

The second flexible printed circuit substrate may further include a second connection pad connected to the second side of the integrated module; and a second connecting portion connecting the second connecting pad and the second external connecting terminal.

A third connection pad and a fourth connection pad disposed on the third surface may be further included, the third connection pad may be connected to the first connection pad, and the fourth connection pad may be connected to the second connection pad.

In a horizontal direction with respect to the third surface, the first internal connection terminal, the second internal connection terminal, the second shunt resistor, the second protection IC chip, and the second field effect transistor may be disposed between the third connection pad and the fourth connection pad.

The first internal connection terminal may be electrically connected to the first external connection terminal, and the second internal connection terminal may be electrically connected to the second external connection terminal.

A rechargeable battery according to the present disclosure includes an electrode assembly including an electrode lead; a case accommodating the electrode assembly; and the circuit board assembly described above electrically connected to the electrode lead.

The electrode assembly may include a first electrode and a second electrode, and a separator disposed between the first electrode and the second electrode, the electrode lead of the first electrode may be connected to the first internal connection terminal, and the electrode lead of the second electrode may be connected to the second internal connection terminal.

According to embodiments of the present disclosure, the current flow in an integrated module may be made more efficient.

### BRIEF DESCRIPTION OF THE DRAWINGS

The following drawings attached to this specification illustrate preferred embodiments of the present invention and, together with the detailed description of the invention described below, serve to further understand the technical idea of the present invention; therefore, the present invention should not be interpreted as being limited to matters described in such drawings.

FIG. 1 is a perspective view of a rechargeable battery including a circuit board assembly according to one embodiment of the present disclosure.

FIG. 2 is an exploded perspective view of the rechargeable battery according to FIG. 1.

FIG. 3 is a perspective view of a circuit board assembly according to an embodiment of the present disclosure.

FIG. 4 is a side view of an integrated module according to an embodiment of the present disclosure.

FIG. 5 is a schematic plan view of an integrated module according to an embodiment of the present disclosure.

FIG. 6 is a rear view of an integrated module according to an embodiment of the present disclosure.

FIG. 7 is a schematic diagram illustrating the current flow of an integrated module according to an embodiment of the present disclosure.

### DETAILED DESCRIPTION OF THE EMBODIMENTS

The present disclosure will be described hereinafter with reference to the accompanying drawings, in which exemplary embodiments are shown. As those skilled in the art would realize, the described embodiments may be modified in various different ways, all without departing from the spirit or scope of the present disclosure.

Descriptions of parts not related to the present disclosure are omitted, and like reference numerals designate like elements throughout the specification.

Further, since sizes and thicknesses of constituent members shown in the accompanying drawings are given for better understanding and ease of description, the present disclosure is not limited to the illustrated sizes and thicknesses. In the drawings, the thickness of layers, films, panels, regions, areas, etc., may be exaggerated for clarity.

It will be understood that when an element such as a layer, film, region, or substrate is referred to as being “on” another element, it can be directly on the other element or intervening elements may also be present. In contrast, when an element is referred to as being “directly on” another element, there are no intervening elements present. Further, in the specification, the word “on” or “above” means positioned on or below the object portion, and does not necessarily mean positioned on the upper side of the object portion based on a gravitational direction.

In addition, unless explicitly described to the contrary, the word “comprise”, and variations such as “comprises” or “comprising”, will be understood to imply the inclusion of stated elements but not the exclusion of any other elements.

Further, throughout the specification, the phrase “in a plan view” means viewing a target portion from the top, and the phrase “in a cross-sectional view” means viewing a cross-section formed by vertically cutting a target portion from the side.

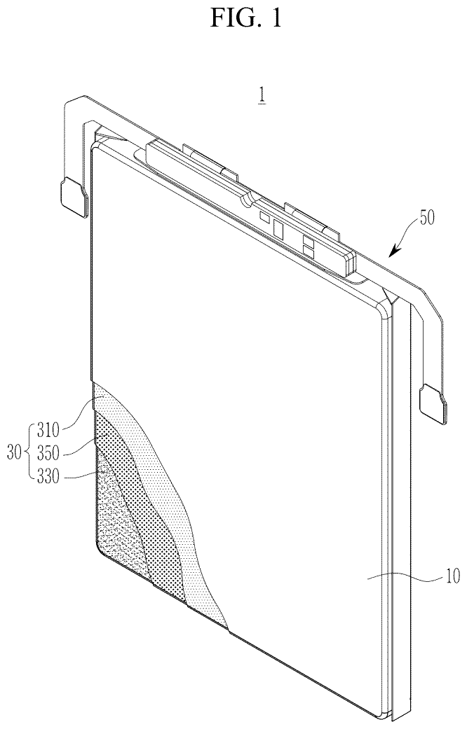

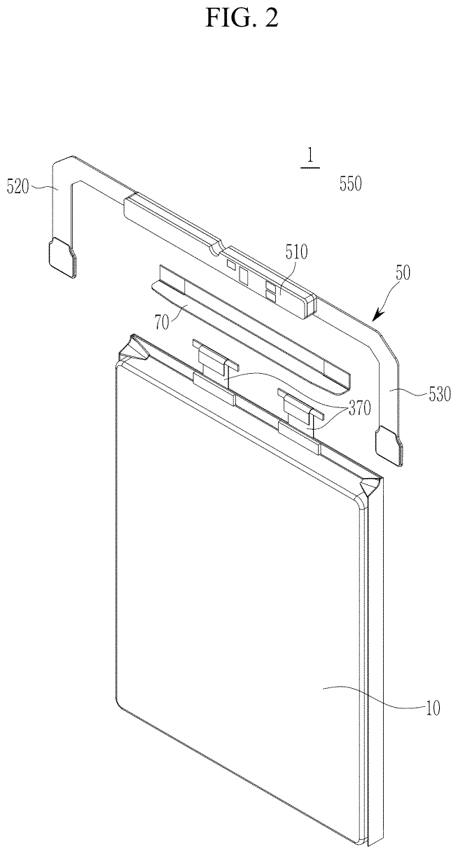

FIG. 1 is a perspective view of a rechargeable battery including a circuit board assembly according to an embodiment of the present disclosure, and FIG. 2 is an exploded perspective view of the rechargeable battery according to FIG. 1.

Referring to FIG. 1 and FIG. 2, a rechargeable battery 1 according to the present embodiment includes a case 10, an electrode assembly 30 accommodated in the case 10, and a circuit board assembly 50 electrically connected to the electrode assembly 30. In this embodiment, the case 10 is a pouch type made of laminate film or plastic. In other embodiments, the case 10 may also be in a shape of a can (e.g., cylindrical or prismatic) made of metal.

The electrode assembly 30 may include a first electrode 310, a second electrode 330, and a separator 350 interposed between the first electrode 310 and the second electrode 330. The first electrode 310 and the second electrode 330 may be electrodes having different polarities. For example, if the first electrode 310 is a positive electrode, the second electrode 330 may be a negative electrode, and vice versa. Each of the first electrode 310 and the second electrode 330 may include a substrate and an active material layer positioned on at least one surface of the substrate. The substrate provides a path for charge generated in the active material layer to move and supports the active material layer.

The electrode assembly 30 may be a stack type in which the first electrode 310 and the second electrode 330 are stacked with the separator 350 in between, and such stacks are repeatedly stacked. In other embodiments, the electrode assembly 30 may be a wound type in which the first electrode 310 arranged on one surface of the separator 350 and the second electrode 330 arranged on the other surface of the separator 350 are wound while maintaining a laminated state.

The electrode assembly 30 may further include an electrode lead 370. The electrode lead 370 may be an extension of the substrate of each electrode 310 and 330 to which the active material layer is not applied. The electrode assembly 30 may be electrically connected to an external component via the electrode lead 370. A circuit board assembly 50 may be connected to the electrode lead 370.

The circuit board assembly 50 may include an integrated module 510, and a first flexible printed circuit board 520 and a second flexible printed circuit board 530 connected thereto. The integrated module 510 may be a SIP (system in package) module in which a number of electronic components are mounted on a substrate.

The first flexible printed circuit board 520 is connected to a first side of the integrated module 510. The second flexible printed circuit board 530 is connected to a second side of the integrated module 510.

The rechargeable battery 1 according to the present embodiment may further include an insulating member 70 positioned between the circuit board assembly 50 and the case 10. The insulating member 70 may have a configuration in which two faces are connected at a right angle. The insulating member 70 may be composed of an insulating material and prevent an unintended electrical connection between the electrode assembly 30 and the circuit board assembly 50.

The circuit board assembly 50 electrically connected to then electrode assembly 30 may transmit the information of the electrode assembly 30 to outside or transmit an external signal to the electrode assembly 30. Here, the outside may be outside of the rechargeable battery 1.

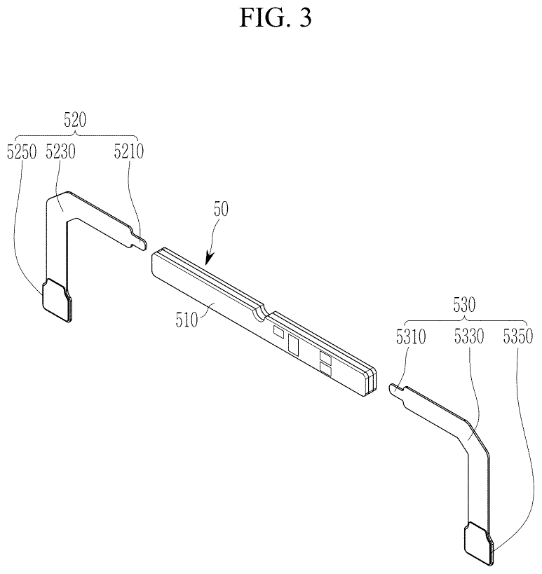

FIG. 3 is a perspective view of a circuit board assembly according to an embodiment of the present disclosure.

Referring to FIG. 3, as described above, the circuit board assembly 50 according to the present embodiment may include an integrated module 510, a first flexible printed circuit board 520 connected to the integrated module 510, and a second flexible printed circuit board 530 connected to the integrated module 510.

The first flexible printed circuit board 520 includes a first connection pad 5210 and a first external connection terminal 5250. A first connection portion 5230 connects the first connection pad 5210 and the first external connection terminal 5250.

The second flexible printed circuit board 530 includes a second connection pad 5310 and a second external connection terminal 5350. A second connection portion 5330 connects the second connection pad 5310 and the second external connection terminal 5250.

The first connection pad 5210 is connected to a first side of the integrated module 510, and the second connection pad 5310 is connected to a second side of the integrated module 510. The first external connection terminal 5250 and the second external connection terminal 5250 are each connected to outside of the rechargeable battery 1.

The integrated module 510 according to the present embodiment is described in detail below.

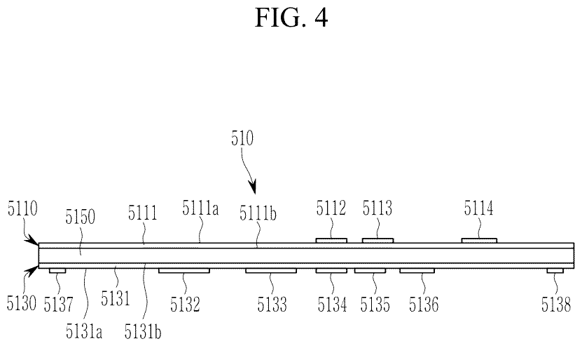

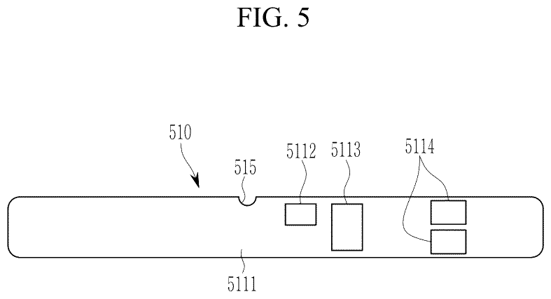

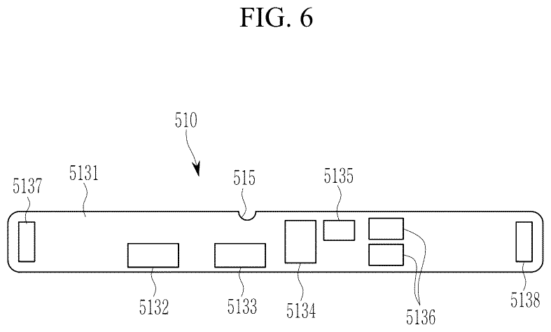

FIG. 4 is a side view of an integrated module according to an embodiment of the present disclosure, FIG. 5 is a plan view of an integrated module according to an embodiment of the present disclosure, and FIG. 6 is a back view of an integrated module according to an embodiment of the present disclosure.

Referring to FIGS. 4 to 6, the integrated module 510 according to the present embodiment includes a first substrate layer 5110 and a second substrate layer 5130 having a rectangular hexahedron shape and facing each other. A conductive pattern layer 5150 is positioned between the first substrate layer 5110 and the second substrate layer 5130.

The first substrate layer 5110 includes a first printed circuit board 5111 including a first surface 5111a and a second surface 5111b facing each other. Rechargeable battery protection circuit components 5112, 5113, and 5114 positioned on the first surface 5111a.

The second substrate layer 5130 includes a second printed circuit board 5131 including a third surface 5131a and a fourth surface 5131b facing each other. A first internal connection terminal 5132, a second internal connection terminal 5133, rechargeable battery protection circuit components 5134, 5135, and 5136, a third connection pad 5137, and a fourth connection pad 5138 are positioned on the third surface 5131a.

The conductive pattern layer 5150 is located on the second surface 5111b and the fourth surface 5131b. The conductive pattern layer 5150 may be composed of multiple layers.

The integrated module 510 according to the present embodiment may further include an alignment mark 515. The alignment mark 515 may be a groove formed in a side of the integrated module 510. These alignment mark(s) 515 may be utilized when connecting the circuit board assembly 50 and the electrode assembly 30.

The rechargeable battery protection circuit components 5112, 5113, and 5114 provided on the first surface 5111a include a first protection integrated circuit chip 5112, a first shunt resistor 5113, and a first field effect transistor (FET) 5114. The first protection IC chip 5112, the first shunt resistor 5113, and the first field effect transistor 5114 may be mounted on the first surface 5111a.

The rechargeable battery protection circuit components 5134, 5135, 5136 provided on the third surface 5131a include a second shunt resistor 5134, a second protection IC chip 5135, and a second field effect transistor 5136. The second shunt resistor 5134, the second protection IC chip 5135, and the second field effect transistor 5136 may be mounted on the third surface 5131a.

The first protection IC chip 5112 and the second protection IC chip 5135 may each include a reference voltage setting unit, a comparison unit for comparing a reference voltage with a charge/discharge voltage, an overcurrent detection unit, and a charge/discharge detection unit. The criteria for determining the charge and discharge status may be changed to specifications requested by a user, and the charge/discharge status is determined by recognizing each voltage difference between the terminals of the first protection IC chip 5112 and the second protection IC chip 5135 based on the set criteria.

The first field effect transistor 5114 and the second field effect transistor 5136 function as electrical switches that can block a current according to signals from the first protection IC chip 5112 and the second protection IC chip 5135. For example, the first protection IC chip 5112 and the second protection IC chip 5135 may turn off the first field effect transistor 5114 and/or the second field effect transistor 5136 when the rechargeable battery 1 reaches an over-discharge state, e.g., during the discharge. Further, when an overcurrent flows, the second field effect transistor 5136 may be turned off during the charging, and the first field effect transistor 5114 may be turned off during the discharging.

The first shunt resistor 5113 and the second shunt resistor 5134 have very low resistance values and are used to measure the current flowing in the circuit.

The first internal connection terminal 5132 and the second internal connection terminal 5133 are positioned adjacent to each other and are each connected to the electrode lead 370 of the electrode assembly 30. For example, the first internal connection terminal 5132 may be connected to the electrode lead 370 that extends from the first electrode 310 and the second internal connection terminal 5133 may be connected to the electrode lead 370 that extends from the second electrode 330.

The third connection pad 5137 is connected to the first connection pad 5210 included in the first flexible printed circuit board 520, and the fourth connection pad 5138 is connected to the second connection pad 5310 included in the second flexible printed circuit board 530. Accordingly, the first flexible printed circuit board 520 and the second flexible printed circuit board 530 may each be connected to the integrated module 510.

The first internal connection terminal 5132 is electrically connected to the first external connection terminal 5250 through the third connection pad 5137 and the first connection pad 5210. The second internal connection terminal 5133 is electrically connected to the second external connection terminal 5350 through the fourth connection pad 5138 and the second connection pad 5310.

The first protection IC chip 5112, the first shunt resistor 5113, and the first field effect transistor 5114 may be sequentially positioned in a horizontal direction on the first surface 5111a. The second shunt resistor 5134, the second protection IC chip 5135, and the second field effect transistor 5136 can be sequentially positioned in a horizontal direction on the third surface 5131a.

The third connection pad 5137 and the fourth connection pad 5138 may each be located at opposite edges of the third surface 5131a. That is, in the horizontal direction with respect to the third surface 5131a, the first internal connection terminal 5132, the second internal connection terminal 5133, the second shunt resistor 5134, the second protection IC chip 5135, and the second field effect transistor 5136 may be positioned between the third connection pad 5137 and the fourth connection pad 5138. Also, in the depicted configuration, in the horizontal direction for the third surface 5131a, the first internal connection terminal 5132 may be positioned adjacent to the third connection pad 5137. Further, the second shunt resistor 5134, the second protection IC chip 5135, and the second field effect transistor 5136 may be positioned between the second internal connection terminal 5133 and the fourth connection pad 5138.

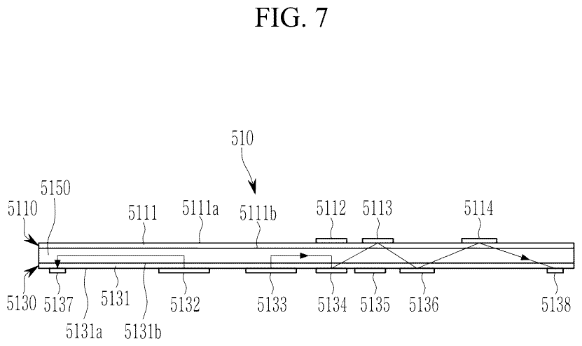

The rechargeable battery protection circuit components 5112, 5113, and 5114 located on the first surface 5111a do not overlap the first internal connection terminal 5132 and the second internal connection terminal 5133 in the vertical direction on the first surface 5111a. That is, as shown in FIG. 4, in the horizontal direction, the second internal connection terminal 5133 may be located between the first internal connection terminal 5132 and the rechargeable battery protection circuit components 5112, 5113, 5114, 5134, 5135, and 5136 located on the first surface 5111a and the third surface 5131a. With this arrangement of the first internal connection terminal 5132, the second internal connection terminal 5133, and the rechargeable battery protection circuit components 5112, 5113, 5114, 5134, 5135, and 5136, the current flow between the second internal connection terminal 5133 and the second external connection terminal 5350 does not bypass the interior of the integrated module. This is explained with reference to FIG. 7.

FIG. 7 is a schematic diagram illustrating the current flow of an integrated module according to an embodiment of the present disclosure. Referring to FIG. 7, current flows from the first internal connection terminal 5132 to the third connection pad 5137. Accordingly, since the third connection pad 5137 is connected to the first connection pad 5210, the first internal connection terminal 5132 is electrically connected to the first external connection terminal 5250 through the third connection pad 5137 and the first connection pad 5210.

The current flowing from the second internal connection terminal 5133 to the fourth connection pad 5138 does not bypass the interior of the integrated module 510. Rather, the current flows from the second internal connection terminal 5133 to the fourth connection pad 5138 through the second shunt resistor 5134, the first shunt resistor 5113, the second field effect transistor 5136, and the first field effect transistor 5114. Accordingly, since the fourth connection pad 5138 is connected to the second connection pad 5310, the second internal connection terminal 5133 is electrically connected to the second external connection terminal 5350 through the fourth connection pad 5138 and the second connection pad 5310.

With the arrangement of components, the first internal connection terminal 5132, the second internal connection terminal 5133, and the rechargeable battery protection circuit components 5112, 5113, 5114, 5134, 5135, and 5136 are arranged on the first substrate layer 5110 and the second substrate layer 5130 of the integrated module 510, the first internal connection terminal 5132 and the second internal connection terminal 5133 are arranged adjacently, and the second internal connection terminal 5133 is arranged between the first internal connection terminal 5132 and the rechargeable battery protection circuit components 5112, 5113, 5114, 5134, 5135, and 5136. Thus, the current flow from the second internal connection terminal 5133 to the fourth connection pad 5138 does not bypass the inside the integrated module 510, and the efficiency of the current may thereby be increased.

The rechargeable battery protection circuit components according to the present embodiment are exemplary. The configuration or number of the rechargeable battery protection circuit components may be appropriately modified according to the additional functions of the protection circuit.

While this disclosure has been described in connection with what is presently considered to be practical exemplary embodiments, it is to be understood that the disclosure is not limited to the disclosed embodiments. Rather, the disclosure covers various modifications and equivalent arrangements.

### DESCRIPTION OF SYMBOLS

1: rechargeable battery
10: case
30: electrode assembly
50: circuit board assembly
70: insulating member
310: first electrode
330: second electrode
350: separator
370: electrode terminal
510: integrated module
520: first flexible printed circuit substrate
530: second flexible printed circuit substrate
5110: first substrate layer
5111a: first surface
5111b: second surface
5112: first protection IC chip
5113: first shunt resistor
5114: first field effect transistor
5130: second substrate layer
5131a: third surface
5131b: fourth surface
5132: first internal connection terminal
5133: second internal connection terminal
5134: second shunt resistor
5135: second protection IC chip
5136: second field effect transistor
5137: third connection pad
5138: fourth connection pad
5150: conductive pattern layer
5210: first connection pad
5230: first connection portion
5250: first external connection terminal
5310: second connection pad
5330: second connection portion
5350: second external connection terminal

What is claimed is:

1. A circuit board assembly comprising:
an integrated module comprising a first internal connection terminal and a second internal connection terminal each of which is connected to an electrode assembly of a rechargeable battery, the integrated module also comprising a rechargeable battery protection circuit component;
a first flexible printed circuit board connected to a first side of the integrated module and comprising a first external connection terminal connected to outside of the circuit board assembly; and
a second flexible printed circuit board connected to a second side of the integrated module and comprising a second external connection terminal connected to outside of the circuit board assembly,
wherein in a horizontal direction for the integrated module, (i) the first internal connection terminal and the second internal connection terminal are disposed adjacent to each other, and (ii) the second internal connection terminal is positioned between the first internal connection terminal and the rechargeable battery protection circuit component.

2. The circuit board assembly as claimed in claim 1, wherein the integrated module comprises:
a first substrate layer and a second substrate layer facing to each other; and
a conductive pattern layer disposed between the first substrate layer and the second substrate layer.

3. The circuit board assembly as claimed in claim 2, wherein: the first substrate layer comprises a first printed circuit board including first and second surfaces facing each other,
wherein the second substrate layer comprises a second printed circuit board including third and fourth surfaces facing each other,
wherein the conductive pattern layer is disposed between the second surface and the fourth surface, and
wherein the first internal connection terminal and the second internal connection terminal are disposed on the third surface.

4. The circuit board assembly as claimed in claim 3, wherein the rechargeable battery protective circuit component comprises:
a first protection IC chip, a first shunt resistor, and a first field effect transistor disposed on the first surface; and
a second shunt resistor, a second protection IC chip, and a second field effect transistor disposed on the third surface.

5. The circuit board assembly as claimed in claim 4, wherein the first flexible printed circuit substrate further comprises:
a connection pad connected to the first side of the integrated module; and
a connecting portion connecting the connecting pad and the first external connecting terminal.

6. The circuit board assembly as claimed in claim 5, wherein the connection pad is a first connection pad and the connecting portion is a first connecting portion, and
wherein the second flexible printed circuit substrate further comprises:
a second connection pad connected to the second side of the integrated module; and
a second connecting portion connecting the second connecting pad and the second external connecting terminal.

7. The circuit board assembly as claimed in claim 6, further comprising a third connection pad and a fourth connection pad disposed on the third surface,
wherein the third connection pad is connected to the first connection pad, and
the fourth connection pad is connected to the second connection pad.

8. The circuit board assembly as claimed in claim 7, wherein in a horizontal direction, the first internal connection terminal, the second internal connection terminal, the second shunt resistor, the second protection IC chip, and the second field effect transistor are disposed between the third connection pad and the fourth connection pad.

9. The circuit board assembly as claimed in claim 8, wherein the first internal connection terminal is electrically connected to the first external connection terminal, and the second internal connection terminal is electrically connected to the second external connection terminal.

10. A rechargeable battery comprising:
an electrode assembly comprising an electrode lead;
a case accommodating the electrode assembly; and
the circuit board assembly as claimed in claim 1 electrically connected to the electrode lead.

11. The rechargeable battery as claimed in claim 10, wherein the electrode assembly comprises a first electrode, a second electrode, and a separator disposed between the first electrode and the second electrode,
wherein the electrode lead of the first electrode is connected to the first internal connection terminal, and
wherein the electrode lead of the second electrode is connected to the second internal connection terminal.
